(19) United States
(12) Patent Application Publication
(10) Pub. No.: US 2025/0254834 A1
(43) Pub. Date: Aug. 7, 2025

(54) GRAVITY- AND MICRO-NANO STRUCTURE-ENHANCED THERMOSYPHON HEAT SINK AND PREPARATION METHOD THEREOF

(71) Applicant: XI'AN JIAOTONG UNIVERSITY, Xi'an (CN)

(72) Inventors: Xiaoping YANG, Xi'an (CN); Shichao BU, Xi'an (CN); Zhuye JIANG, Xi'an (CN); Yonghai ZHANG, Xi'an (CN); Jinjia WEI, Xi'an (CN)

(21) Appl. No.: 19/185,114

(22) Filed: Apr. 21, 2025

(30) Foreign Application Priority Data
Dec. 27, 2024 (CN) 202411954920.7

(51) Int. Cl. H05K 7/20

(52) U.S. Cl. CPC H05K 7/2039

(57) ABSTRACT

A gravity- and micro-nano structure-enhanced thermosyphon heat sink, including a base plate at an evaporation side. A heat dissipation assembly is provided at a top side of the base plate. Fixing assemblies are arranged on two sides and top of the heat dissipation assembly. The base plate has a box-shaped structure. Four corners of the base plate are each provided with a positioning bolt hole. A plurality of support posts and a reinforcement structure are arranged within the base plate. A side wall of the base plate is provided with a port for evacuation and fluid filling.

### CROSS-REFERENCE TO RELATED APPLICATIONS

This application claims the benefit of priority from Chinese Patent Application No. 202411954920.7, filed on Dec. 27, 2024. The content of the aforementioned application, including any intervening amendments made thereto, is incorporated herein by reference in its entirety.

### TECHNICAL FIELD

This application relates to thermosyphon heat sinks, and more particularly to a gravity- and micro-nano structure-enhanced thermosyphon heat sink and a preparation method thereof.

### BACKGROUND

With the development of 5G communication and artificial intelligence technologies, the demand for computing power has surged, and high-performance chips have been continuously developed. However, this also poses a challenge in the dissipation under a high heat flux. Traditional solid-state air-cooled heat sinks have high thermal resistance, large size and heavy weight, making them unsuitable for meeting the cooling demands of current and future high-performance chips. Although direct liquid cooling (immersion-based) and indirect liquid cooling (cold plate-based) offer higher heat dissipation efficiency, they involve high investment and maintenance costs and system complexity. Moreover, the risk of coolant leakage presents a significant challenge to the cooling system. Therefore, further exploring the potential of air-cooling technology remains highly valuable for engineering applications.

In recent years, heat pipe-based technologies such as air-cooled heat pipe arrays, vapor chambers and thermosyphons have been developed. By leveraging the superior heat transfer capability of heat pipes, these technologies significantly increase the effective cooling area and offer advantages such as high cooling capacity, low thermal resistance and excellent temperature uniformity. Among them, heat pipe arrays and vapor chambers demonstrate high cooling efficiency and low thermal resistance. However, their internal working fluid circulation relies on sintered porous wick structures to generate capillary force, resulting in complex manufacturing processes and high production costs. In contrast, thermosyphons utilize gravity-driven fluid circulation, providing simpler construction and reliable performance without requiring intricate wick structures.

Traditional thermosyphons typically operate in a two-dimensional, unidirectional circulation pattern, which results in single-direction vapor diffusion and limits fin arrangement to a single channel, constraining effective cooling area expansion. Thermosyphons achieve heat transfer through boiling-condensation cycles of the internal working fluid, where the combined boiling and condensation thermal resistance typically constitutes 50-70% of the total system resistance. However, the smooth interior surfaces lack sufficient nucleation sites and exhibit poor rewetting capability, which can lead to premature heat transfer degradation when handling high heat flux conditions.

### SUMMARY

An object of the disclosure is to provide a gravity- and micro-nano structure-enhanced thermosyphon heat sink and a preparation method thereof, addressing the issues of conventional thermosyphons having a single vapor diffusion direction, limited expansion of effective heat dissipation area, and the premature deterioration of heat transfer due to the presence of fewer nucleation sites and weak re-wetting ability on smooth surfaces, which fail to meet the heat dissipation requirements of high-heat-flux chips.

Technical solutions of the present disclosure are described as follows.

A gravity- and micro-nano structure-enhanced thermosyphon heat sink, comprising:
a base plate arranged at an evaporation side;
wherein a heat dissipation assembly is provided at a top side of the base plate;
two sides and a top of the heat dissipation assembly are each provided with a fixing assembly;
the base plate has a box-shaped structure;
four corners of the base plate are each provided with a positioning bolt hole;
a plurality of support posts and a reinforcement structure are arranged within the base plate; and
a side wall of the base plate is provided with a port for evacuation and fluid filling.

In some embodiments, the reinforcement structure is provided at a center of the base plate;
the plurality of support posts are evenly distributed around the reinforcement structure; and
bottom sides of the plurality of support posts are fixedly connected to base plate.

In some embodiments, the reinforcement structure comprises a plurality of micro-pin fins; surfaces of the plurality of micro-pin fins, surfaces of the plurality of support posts, and an inner surface of the base plate are each provided with a plurality of nano holes; and bottom ends of the plurality of micro-pin fins are fixedly connected to the base plate.

In some embodiments, the heat dissipation assembly comprises a first mounting partition arranged at the evaporation side and a second mounting partition arranged at a condensation side; a plurality of drawer-type multilayer fins and a plurality of flat tubes are alternately arranged between the first mounting partition and the second mounting partition; the plurality of flat tubes are configured for vapor diffusion; and the first mounting partition is welded to top sides of the plurality of support posts.

In some embodiments, an interior of each of the plurality of flat tubes is configured to be hollow to form a vapor-diffusion channel;
an inner wall of each of the plurality of flat tubes is provided with a plurality of dual-stage radial ridge microgrooves;
the plurality of dual-stage radial ridge microgrooves are arranged in parallel in a height direction of each of the plurality of flat tubes;
each of the plurality of dual-stage radial ridge microgrooves comprises a two-stage recessed groove structure in a height direction of each of the plurality of dual-stage radial ridge microgrooves; and
the two-stage recessed groove structure consists of a first-stage recessed groove and a second-stage recessed groove; and an envelope tangent angle α of the first-stage recessed groove is greater than an envelope tangent angle β of the second-stage recessed groove.

In some embodiments, the fixing assembly comprises a first fixing plate and two second fixing plates; the first fixing plate, the two second fixing plates, the first mounting partition and the second mounting partition are integrally welded to form a chamber in fluid communication.

This application also provides a method for preparing the thermosyphon heat sink, comprising:
machining individual structural components using a machine tool;
forming a plurality of first insertion slots on the first mounting partition, and forming a plurality of second insertion slots on the second mounting partition;
inserting the plurality of flat tubes respectively into the plurality of first insertion slots and the plurality of second insertion slots followed by welding;
mounting the plurality of drawer-type multilayer fins between the first mounting partition and the second mounting partition, wherein the plurality of drawer-type multilayer fins and the plurality of flat tubes are alternately arranged;
welding the first fixing plate on the second mounting partition;
welding the two second fixing plates respectively onto two sides of the first fixing plate; and
connecting lower sides of the two second fixing plates respectively to the first mounting partition and the base plate followed by welding and sealing to obtain the thermosyphon heat sink.

In some embodiments, each of the plurality of support posts has a length of 2-4 mm, a width of 2-4 mm and a height of 2-4 mm;
a spacing between any two adjacent support posts among the plurality of support posts is 2-4 mm; and
the two second fixing plates, the plurality of drawer-type multilayer fins, the second mounting partition and the first fixing plate are each prepared from an aluminum alloy plate.

In some embodiments, the reinforcement structure comprises a plurality of micro-pin fins arranged in an array; the plurality of micro-pin fins each have a columnar structure with a characteristic dimension of 50-500 μm and a height of 50-800 μm; and surfaces of the plurality of micro-pin fins, surfaces of the plurality of support posts, and an inner surface of the base plate are each distributed with nano holes with a characteristic dimension of 0.1-1 μm; and the plurality of micro-pin fins are processed through steps of:
(1) washing the plurality of micro-pin fins sequentially with anhydrous acetone and deionized water followed by drying;
(2) processing the plurality of micro-pin fins 2-5 times using a femtosecond laser; wherein the femtosecond laser has a power of 5-15 W, a scanning speed of 20-150 mm/s, and a processing frequency of 50-200 kHz; and
(3) washing the plurality of micro-pin fins sequentially with anhydrous acetone and deionized water followed by drying.

In some embodiments, an inner wall of each of the plurality of flat tubes is provided with a plurality of dual-stage radial ridge microgrooves; and the plurality of dual-stage radial ridge microgrooves are prepared through steps of:
preparing a stainless steel mold according to an outer contour dimension of each of the plurality of dual-stage radial ridge microgrooves; and
loading an aluminum alloy plate onto the stainless steel mold followed by pressing to form the plurality of dual-stage radial ridge microgrooves, each having a height of 0.5-2 mm, a maximum width of 2-3 mm; and
a spacing between center axes of any two adjacent dual-stage radial ridge microgrooves among the plurality of dual-stage radial ridge microgrooves is 4-6 mm.

Compared to the prior art, the present disclosure has the following beneficial effects.
1. By upgrading the operating mode of conventional thermosyphons from two-dimensional to three-dimensional, widespread vapor diffusion in a multi-dimensional space is achieved. This transformation significantly expands the vapor condensation heat exchange area, thereby enhancing the condensation efficiency of the thermosyphon's condensation side.
2. The present disclosure adopts an innovative biomimetic design inspired by the microscale dual-stage radial ridge structure of a peristome surface of Nepenthes mirabilis (Lour.) Druce, which is applied to an inner wall of the condensation side of the thermosyphon. This design precisely controls the orientation of the condensate film meniscus, ensuring that the condensate efficiently converges at the bottoms of the plurality of dual-stage radial ridge microgrooves. As a result, the maximum film thickness is effectively regulated, allowing the condensate to rapidly flow toward the boiling side. Additionally, this design increases the contact area between vapor and the structured inner wall of the condensation side, further enhancing the thermosyphon's performance.
3. A micro-pin fin-nano hole composite structure is provided on an inner wall surface of the evaporation side, where the plurality of nano holes offer abundant nucleation sites to enhance the boiling heat transfer coefficient, while the plurality of micro-pin fins provide micro liquid layer flow channels in the evaporation region to increase the critical heat flux of boiling heat transfer, thereby improving the heat transfer efficiency on the boiling side of the thermosyphon.

The technical solutions of the present disclosure will be described in further detail below with reference to the accompanying drawings and embodiments.

### BRIEF DESCRIPTION OF THE DRAWINGS

FIG. 1 is a structural diagram of a gravity- and micro-nano structure-enhanced thermosyphon heat sink according to an embodiment of the present disclosure;

FIG. 2 is an exploded view of the thermosyphon heat sink according to an embodiment of the present disclosure;

FIG. 3 is a structural diagram of a plurality of micro-pin fins according to an embodiment of the present disclosure;

FIG. 4 schematically shows a distribution of nano holes on the micro-pin fins according to an embodiment of the present disclosure;

FIG. 5 is an oblique sectional view of a flat tube according to an embodiment of the present disclosure; and

FIG. 6 is a structural diagram of a dual-stage radial ridge microgroove according to an embodiment of the present disclosure.

In the figures: 1—base plate; 110—support post; 111—positioning bolt hole; 112—port; 113—reinforcement structure; 1130—micro-pin fin; 1131—nano hole; 2—first mounting partition; 3—flat tube; 310—vapor-diffusion channel; 311—dual-stage radial ridge microgroove; 4—second fixing plate; 5—drawer-type multilayer fin; 6—second mounting partition; and 7—first fixing plate.

### DETAILED DESCRIPTION OF EMBODIMENTS

In order to make the objects, technical solutions and advantages of the present disclosure clearer, the present disclosure will be described clearly and completely below in conjunction with the accompanying drawings and embodiments. Obviously, described herein are merely some embodiments of the present disclosure, rather than all embodiments. The components of embodiments of the present disclosure described and shown in the accompanying drawings may be arranged and designed in a variety of different configurations.

Thus, the following detailed description of embodiments of the present disclosure provided in the accompanying drawings is not intended to limit the scope of the present disclosure, but rather represents only selected embodiments of the present disclosure. Based on the embodiments in the present disclosure, all other embodiments obtained by those of ordinary skill in the art without making creative effort shall fall within the scope of the present disclosure defined by the appended claims.

It should be noted that similar reference numerals and letters in the following accompanying drawings indicate similar items. Therefore, once an item is defined in one accompanying drawing, it does not require further definition or explanation in the subsequent accompanying drawings.

Additionally, in the description of the present disclosure, it should be noted that, as used herein, terms “up”, “down”, “left”, “right”, “inner” and “outer” are based on the those shown in the accompanying drawings. These terms are solely for the convenience of describing the present disclosure, and are not intended to indicate or imply that the devices or components must have specific orientations or be constructed and operated in specific orientations. Therefore, these terms should not be understood as limitations of the present disclosure.

In the description of the present disclosure, it should also be noted that, unless otherwise specifically defined, as used herein, terms “arranged”, “mounted”, and “connected” are to be broadly understood. For example, these terms may refer to fixed connections, detachable connections, or integral connections; mechanical connections, electrical connections, direct connections or indirect connections through intermediate media; or communication between two components internally. For those of ordinary skill in the art, the specific meaning of these terms in the present disclosure can be understood based on the particular context.

The technical solutions of the present disclosure will be described in further detail below with reference to the accompanying drawings. Unless otherwise specified, the embodiments and features thereof may be combined with each other without conflict.

The specific model and specifications shall be determined based on the actual specifications of the device. The selection and calculation methods follow conventional techniques in the prior art and will not be elaborated herein.

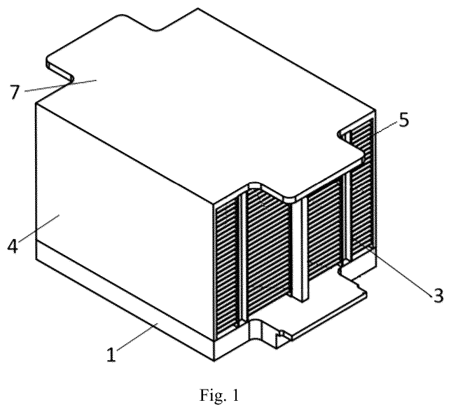

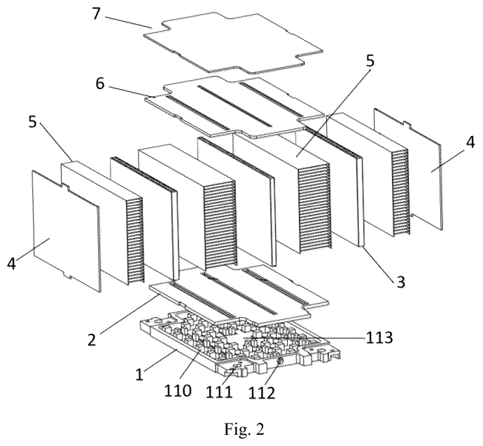

As shown in FIGS. 1-2, an embodiment of the present disclosure provides a gravity- and micro-nano structure-enhanced thermosyphon heat sink, including a base plate 1 arranged at an evaporation side. A heat dissipation assembly is provided at a top side of the base plate 1. Two sides and a top of the heat dissipation assembly are each provided with a fixing assembly. The base plate 1 has a box-shaped structure. Four corners of the base plate 1 are each provided with a positioning bolt hole 111. A plurality of support posts 110 and a reinforcement structure 113 are arranged within the base plate 1. A side wall of the base plate 1 is provided with a port 112 for evacuation and fluid filling.

A lower surface of the base plate 1 is attached to a chip via a thermal interface material. Positioning and fastening are achieved through the positioning bolt hole 111. The port 112 is connected to a pipe for evacuation and fluid filling, so as to perform evacuation and liquid filling operations on a heat sink.

The reinforcement structure 113 is provided at a center of the base plate 1. The plurality of support posts 110 are evenly distributed around the reinforcement structure 113. Bottom sides of the plurality of support posts 110 are fixedly connected to the base plate 1.

The heat dissipation assembly includes a first mounting partition 2 arranged at the evaporation side and a second mounting partition 6 arranged at a condensation side. A plurality of drawer-type multilayer fins 5 and a plurality of flat tubes 3 are alternately arranged between the first mounting partition 2 and the second mounting partition 6. The plurality of flat tubes 3 are configured for vapor diffusion. The first mounting partition 2 is welded to top sides of the plurality of support posts 110.

Each of the plurality of support posts 110 is configured as a square column. A top portion of each of the plurality of support posts 110 is fixedly connected to the first mounting partition 2 via a brazing process to enhance pressure resistance and prevent deformation caused by excessive internal pressure of the heat sink.

The fixing assembly includes a first fixing plate 7 and two second fixing plates 4. The first fixing plate 7, the two second fixing plates 4, the first mounting partition 2 and the second mounting partition 3 are integrally welded to form a chamber in fluid communication.

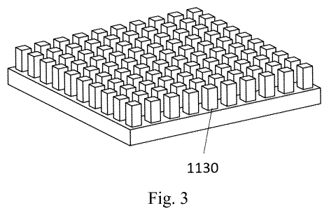

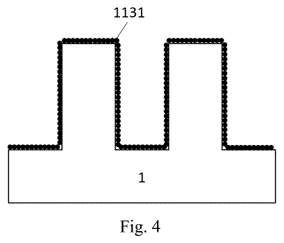

As shown in FIGS. 3-4, the reinforcement structure 113 includes a plurality of micro-pin fins 1130. Surfaces of the plurality of micro-pin fins 1130, surfaces of the plurality of support posts 110, and an inner surface of the base plate 1 are each provided with a plurality of nano holes 1131. Bottom ends of the plurality of micro-pin fins 1130 are fixedly connected to the base plate 1. Specifically, each of the plurality of nano holes 1131 is configured as a nanometer-scale pit with a characteristic dimension in the tens of nanometers, the exact size of each of the plurality of nano holes 1131 is determined by the process flow and specific application requirements.

The plurality of micro-pin fins 1130 can significantly increase a specific surface area of an upper surface of the base plate 1. Additionally, the array-arranged micro-pin fins 1130 provide capillary force, enhancing the liquid replenishment capability of the heat transfer surface, delaying the deterioration of boiling heat transfer on the upper surface of the base plate 1, and increasing the critical heat flux. The plurality of nano holes 1131 provide a large number of nucleation sites for boiling and vaporization, significantly improving the boiling heat transfer coefficient, thereby effectively reducing a thermal resistance of the heat sink.

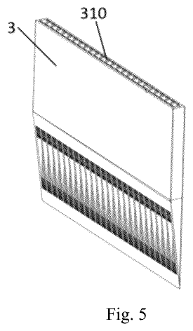

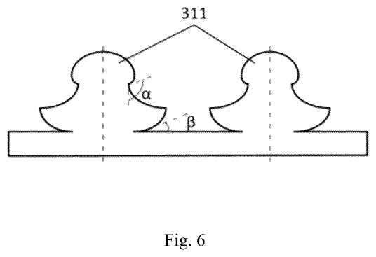

As shown in FIGS. 5-6, each of the plurality of flat tubes 3 includes a plurality of vapor-diffusion channels 310 and a plurality of dual-stage radial ridge microgrooves 311. The plurality of dual-stage radial ridge microgrooves 311 are arranged in parallel in a height direction of each of the plurality of flat tubes 3. Each of the plurality of dual-stage radial ridge microgrooves 311 includes a two-stage recessed groove structure in a height direction of each of the plurality of dual-stage radial ridge microgrooves 311. The two-stage recessed groove structure consists of a first-stage recessed groove and a second-stage recessed groove. An envelope tangent angle α of the first-stage recessed groove is greater than an envelope tangent angle β of the second-stage recessed groove, that is, a characteristic dimension of the second-stage recessed groove is smaller than that of the first-stage recessed groove.

By means of the above structure, the second-stage recessed groove can generate a larger capillary force. Driven by the capillary force gradient, the condensate automatically moves and converges from a top to a bottom of each of the plurality of dual-stage radial ridge microgrooves. This not only reduces the condensate film thickness at the top of each of the plurality of dual-stage radial ridge microgrooves, but also increases the condensate weight at the bottom of each of the plurality of dual-stage radial ridge microgrooves, thereby improving condensation heat transfer efficiency and facilitating the rapid detachment and flow of the condensate onto the upper surface of the base plate 1. As a result, liquid replenishment is accelerated, thereby enhancing the thermosyphon heat sink's maximum heat dissipation capacity. The plurality of dual-stage radial ridge microgrooves significantly expands the effective condensation area on inner walls of the plurality of flat tubes 3, thereby improving the condensation efficiency and reducing the thermal resistance of the thermosyphon heat sink.

The above components are all made of aluminum alloy.

An operating principle of the thermosyphon heat sink is as follows. A working fluid is sealed inside the thermosyphon heat sink, primarily concentrated in a chamber between the base plate 1 and the first mounting partition 2. The lower surface of the base plate 1 is attached to the chip. The positioning bolt hole 111 is configured to facilitate alignment and fastening, ensuring secure attachment for efficient heat transfer. Upon absorbing heat from the chip, the base plate 1 causes the working fluid on its upper surface to boil and vaporize. The generated vapor diffuses upward into the plurality of vapor-diffusion channels 310 of the plurality of flat tubes 3, where heat is conducted through walls of the plurality of flat tubes 3 to fin surfaces of the plurality of drawer-type multilayer fins 5, enabling heat exchange with the surrounding air. After releasing heat, the vapor condenses and liquefies back into the working fluid, which then flows back to the chamber between the base plate 1 and the first mounting partition 2 under the influence of gravity to continue the boiling process, thereby repeating the cycle.

The working fluid sealed inside the thermosyphon heat sink can be a low-boiling-point refrigerant, such as 1,1,1,2-tetrafluoroethane (R134a), 1,1,1,3,3-pentafluoropropane (R245fa) or trans-1-chloro-3,3,3-trifluoropropene (R1233zd(E)); or a low-boiling-point fluorinated coolant with a boiling point of 10-65° C., such as Methoxy-nonafluorobutane (HFE-7100™) or 1,1,1,2,2,3,4,5,5,5-Decafluoro-3-methoxy-4-(trifluoromethyl) pentane (Novec™ 649); or an alcohol-based working fluid, such as methanol or ethanol.

The present disclosure also provides a method for preparing the thermosyphon heat sink provided herein, which is performed as follows. Individual structural components are machined using a machine tool. A plurality of first insertion slots are formed on the first mounting partition 2, and a plurality of second insertion slots are formed on the second mounting partition 6. The plurality of flat tubes 3 are respectively inserted into the plurality of first insertion slots and the plurality of second insertion slots followed by welding. The plurality of drawer-type multilayer fins 5 are mounted between the first mounting partition 2 and the second mounting partition 6, where the plurality of drawer-type multilayer fins 5 and the plurality of flat tubes 3 are alternately arranged. The first fixing plate 7 is welded on the second mounting partition 6. The two second fixing plates 4 are respectively welded onto two sides of the first fixing plate 7. Lower sides of the two second fixing plates 4 are respectively connected to the first mounting partition 2 and the base plate 1 followed by welding and sealing to obtain the thermosyphon heat sink.

Each of the plurality of support posts 110 has a length of 2-4 mm, a width of 2-4 mm and a height of 2-4 mm. A spacing between any two adjacent support posts 110 among the plurality of support posts 110 is 2-4 mm. The two second fixing plates 4, the plurality of drawer-type multilayer fins 5, the second mounting partition 6 and the first fixing plate 7 are each prepared from an aluminum alloy plate.

The reinforcement structure 113 includes the plurality of micro-pin fins 1130 are arranged in an array. The plurality of micro-pin fins 1130 each have a columnar structure with a characteristic dimension of 50-500 μm and a height of 50-800 μm. Surfaces of the plurality of micro-pin fins 1130, surfaces of the plurality of support posts 110, and the inner surface of the base plate 1 are each distributed with nano holes 1131 with a characteristic dimension of 0.1-1 μm. The characteristic dimension refers to a length and a width of each of the plurality of micro-pin fins 1130 as well as a vertical spacing between any two adjacent micro-pin fins 1130.

The plurality of micro-pin fin 1130 are processed through the following steps.
Step (1) The plurality of micro-pin fins 1130 are sequentially washed with anhydrous acetone and deionized water, and dried.
Step (2) The plurality of micro-pin fins 1130 are processed 2-5 times using a femtosecond laser, where the femtosecond laser has a power of 5-15 W, a scanning speed of 20-150 mm/s and a processing frequency of 50-200 kHz.
Step (3) The plurality of micro-pin fins 1130 are sequentially washed again with anhydrous acetone and deionized water and dried.

In some embodiments, an inner wall of each of the plurality of flat tubes 3 is provided with the plurality of dual-stage radial ridge microgrooves 311. The plurality of dual-stage radial ridge microgrooves 311 are prepared through the following steps. A stainless steel mold is prepared according to an outer contour dimension of each of the plurality of dual-stage radial ridge microgrooves 311. An aluminum alloy plate is loaded onto the stainless steel mold and then pressed to form the plurality of dual-stage radial ridge microgrooves 311, each having a height of 0.5-2 mm, a maximum width of 2-3 mm. A spacing between center axes of any two adjacent dual-stage radial ridge microgrooves 311 among the plurality of dual-stage radial ridge microgrooves 311 is 4-6 mm.

By adopting the aforementioned structure, the gravity- and micro-nano structure-enhanced thermosyphon heat sink provided herein and its preparation method can overcome the limitations of conventional thermosyphons, including single-direction vapor diffusion, restricted heat dissipation area, and premature heat transfer deterioration due to presence of fewer nucleation sites and weak re-wetting ability during the boiling heat transfer process on smooth surfaces, which fail to meet the heat dissipation requirements of high-heat-flux chips.

It should be noted that the above embodiments are only used to illustrate the technical solutions of the present disclosure, rather than limiting the disclosure. Although the present disclosure has been described in detail with reference to the above embodiments, those of ordinary skill in the art could still make various modifications and substitutions to the technical solutions recited in the above embodiments. It should be understood that such modifications or substitutions made without departing from the spirit of the disclosure shall fall within the scope of the present disclosure defined by the appended claims.

What is claimed is:

1. A gravity- and micro-nano structure-enhanced thermosyphon heat sink, comprising:
a base plate arranged at an evaporation side;
wherein a heat dissipation assembly is provided at a top side of the base plate;
two sides and a top of the heat dissipation assembly are each provided with a fixing assembly;
the base plate has a box-shaped structure;
four corners of the base plate are each provided with a positioning bolt hole;
a plurality of support posts and a reinforcement structure are arranged within the base plate; and
a side wall of the base plate is provided with a port for evacuation and fluid filling.

2. The thermosyphon heat sink according to claim 1, wherein the reinforcement structure is provided at a center of the base plate;
the plurality of support posts are evenly distributed around the reinforcement structure; and
bottom sides of the plurality of support posts are fixedly connected to the base plate.

3. The thermosyphon heat sink according to claim 1, wherein the reinforcement structure comprises a plurality of micro-pin fins; surfaces of the plurality of micro-pin fins, surfaces of the plurality of support posts, and an inner surface of the base plate are each provided with a plurality of nano holes; and bottom ends of the plurality of micro-pin fins are fixedly connected to the base plate.

4. The thermosyphon heat sink according to claim 1, wherein the heat dissipation assembly comprises a first mounting partition arranged at the evaporation side and a second mounting partition arranged at a condensation side; a plurality of drawer-type multilayer fins and a plurality of flat tubes are alternately arranged between the first mounting partition and the second mounting partition; the plurality of flat tubes are configured for vapor diffusion; and the first mounting partition is welded to top sides of the plurality of support posts.

5. The thermosyphon heat sink according to claim 4, wherein an interior of each of the plurality of flat tubes is configured to be hollow to form a vapor-diffusion channel;
an inner wall of each of the plurality of flat tubes is provided with a plurality of dual-stage radial ridge microgrooves;
the plurality of dual-stage radial ridge microgrooves are arranged in parallel in a height direction of each of the plurality of flat tubes;
each of the plurality of dual-stage radial ridge microgrooves comprises a two-stage recessed groove structure in a height direction of each of the plurality of dual-stage radial ridge microgrooves; and
the two-stage recessed groove structure consists of a first-stage recessed groove and a second-stage recessed groove; and an envelope tangent angle α of the first-stage recessed groove is greater than an envelope tangent angle β of the second-stage recessed groove.

6. The thermosyphon heat sink according to claim 4, wherein the fixing assembly comprises a first fixing plate and two second fixing plates; the first fixing plate, the two second fixing plates, the first mounting partition and the second mounting partition are integrally welded to form a chamber in fluid communication.

7. A method for preparing the thermosyphon heat sink according to claim 6, comprising:
machining individual structural components using a machine tool;
forming a plurality of first insertion slots on the first mounting partition, and forming a plurality of second insertion slots on the second mounting partition;
inserting the plurality of flat tubes respectively into the plurality of first insertion slots and the plurality of second insertion slots followed by welding;
mounting the plurality of drawer-type multilayer fins between the first mounting partition and the second mounting partition, wherein the plurality of drawer-type multilayer fins and the plurality of flat tubes are alternately arranged;
welding the first fixing plate on the second mounting partition;
welding the two second fixing plates respectively onto two sides of the first fixing plate; and
connecting lower sides of the two second fixing plates respectively to the first mounting partition and the base plate followed by welding and sealing to obtain the thermosyphon heat sink.

8. The method according to claim 7, wherein each of the plurality of support posts has a length of 2-4 mm, a width of 2-4 mm and a height of 2-4 mm;
a spacing between any two adjacent support posts among the plurality of support posts is 2-4 mm; and
the two second fixing plates, the plurality of drawer-type multilayer fins, the second mounting partition and the first fixing plate are each prepared from an aluminum alloy plate.

9. The method according to claim 7, wherein the reinforcement structure comprises a plurality of micro-pin fins arranged in an array; the plurality of micro-pin fins each have a columnar structure with a characteristic dimension of 50-500 μm and a height of 50-800 μm; and surfaces of the plurality of micro-pin fins, surfaces of the plurality of support posts, and an inner surface of the base plate are each distributed with nano holes with a characteristic dimension of 0.1-1 μm; and
the plurality of micro-pin fins are processed through steps of:
(1) washing the plurality of micro-pin fins sequentially with anhydrous acetone and deionized water followed by drying;
(2) processing the plurality of micro-pin fins 2-5 times using a femtosecond laser;
wherein the femtosecond laser has a power of 5-15 W, a scanning speed of 20-150 mm/s, and a processing frequency of 50-200 kHz; and
(3) washing the plurality of micro-pin fins sequentially with anhydrous acetone and deionized water followed by drying.

10. The method according to claim 7, wherein an inner wall of each of the plurality of flat tubes is provided with a plurality of dual-stage radial ridge microgrooves; and
the plurality of dual-stage radial ridge microgrooves are prepared through steps of:
preparing a stainless steel mold according to an outer contour dimension of each of the plurality of dual-stage radial ridge microgrooves; and
loading an aluminum alloy plate onto the stainless steel mold followed by pressing to form the plurality of dual-stage radial ridge microgrooves, each having a height of 0.5-2 mm, a maximum width of 2-3 mm, wherein a spacing between center axes of any two adjacent dual-stage radial ridge microgrooves among the plurality of dual-stage radial ridge microgrooves is 4-6 mm.
